(19) United States
(12) Patent Application Publication
(10) Pub. No.: US 2026/0359522 A1
(43) Pub. Date: Nov. 12, 2026

(54) METHOD AND SYSTEM FOR GENERATING OPERATIONAL INSIGHTS FROM EMISSION EFFICIENCY OF AN ASSET

(71) Applicant: Honeywell International Inc., Charlotte, NC (US)

(72) Inventors: Sandhya Beejady, Bangalore (IN); Rajapriyan Thambidurai, Bangalore (IN); Dhandapani Krishnasamy, Hosur (IN); Sridhar Sankaranarayanan, Bangalore (IN)

(21) Appl. No.: 19/204,667

(22) Filed: May 12, 2025

(51) Int. Cl. G06F 30/27

(52) U.S. Cl. CPC G06F 30/27

(57) ABSTRACT

The disclosure relates to a method and system for generating operational insights from the emission efficiency of an asset. The method involves collecting input data at an emission management system. The input data includes at least one of energy inputs and asset operating conditions. Based on the collected data, the system determines the energy output produced by the asset and calculates the emission output using a Predictive Emission Monitoring System (PEMS) or a predefined statistical formulation. The method further includes calculating the emission efficiency of the asset by analyzing the relationship between energy input and emission output. Using this efficiency data, emission limits are identified, including at least one of target high limits, target low limits, warning high limits, and warning low limits. If the identified emission limits require adjustments, the method recommends optimized emission limits in accordance with predefined regulatory or operational thresholds.

### TECHNICAL FIELD

The present disclosure relates to emission management and asset performance optimization. More particularly, the present disclosure pertains to an automated method and system for determining emission efficiency and dynamically setting emission limits based on real-time asset performance.

### BACKGROUND

Traditional emission monitoring techniques primarily focus on absolute emission values, neglecting the efficiency aspect. This oversight may lead to misinterpretation of an asset's actual operational performance. For instance, two assets emitting the same quantity of pollutants might not have the same efficiency; one may be utilizing its input energy more effectively than the other.

Emission efficiency of an asset reflects its performance by analyzing the relationship between the energy input and the emission output during operations such as combustion processes. Assets that exhibit excessive emissions relative to their input energy consumption may indicate inefficiencies, improper combustion, or suboptimal operating conditions.

Hence, there is a need for automating the identification of emission limits based on emission efficiency that can provide a realistic approach to monitoring and improving asset performance while ensuring regulatory compliance. Additionally, intelligent insights derived from emission efficiency can enable predictive maintenance, optimization of energy consumption, and achieving long-term emission reduction goals, such as a net-zero carbon footprint.

### SUMMARY

The present disclosure provides an automated system and method for dynamically determining and applying emission limits based on real-time emission efficiency of an asset. The system calculates emission efficiency using asset operational data, including energy input, output, waste energy, and residuals. Based on this efficiency, the system categorizes assets, predicts emission trends, and recommends adjustments to the emission limits, maintenance schedules, and energy optimization strategies.

According to an aspect of the disclosure, a method for generating operational insights from the emission efficiency of an asset is disclosed. The method comprises collecting, at an emission management system, input data associated with the asset, where the input data includes at least one of the energy inputs of the asset and asset operating conditions. The method further comprises determining an energy output produced by the asset based on the collected input data and determining an emission output of the asset using a predictive emission monitoring system (PEMS) or a predefined statistical formulation. The method further comprises calculating an emission efficiency of the asset based on the collected input data and the emission output of the asset and identifying emission limits of the asset based on the calculated emission efficiency, where the emission limits of the asset comprise at least one of target high limits, target low limits, warning high limits, and warning low limits. Lastly, the method comprises recommending ideal emission limits to be applied to the asset if the identified emission limits require adjustments according to predetermined limits.

In some embodiments, the method further comprises calculating an operational efficiency of the asset based on the collected input data and the determined energy output.

In some embodiments, the method further comprises determining a residual waste energy output generated by the asset.

In some embodiments, the predefined statistical formulation for determining the emission output includes at least one of: an empirical model, a mathematical function based on combustion properties, a lookup table of historical emission data, and/or a regression-based predictive model.

In some embodiments, the method further comprises collecting the emission efficiency based on the asset operating conditions over a predetermined period and organizing the emission efficiency to determine threshold percentages for defining the ideal emission limits.

In some embodiments, the method further comprises determining emission values associated with the identified emission limits of the asset, aggregating the identified emission limits of the asset over a predetermined time period based on the determined emission values, obtaining emission limits of a plurality of assets at a site or a region based on the aggregated emission limits of individual assets, and recommending adjusted emission limits for the asset based on the obtained emission limits to align with a net-neutral emission target year.

In some embodiments, the method further comprises predicting year-over-year emission limits of the asset until the net-neutral emission target year.

In some embodiments, the method further comprises adjusting the identified emission limits of the asset based on at least one of: energy optimization measures; predictive maintenance strategies; and green energy utilization.

In some embodiments, calculating the emission efficiency of the asset comprises: computing the emission efficiency as a percentage ratio of the energy inputs to the emission output, classifying one or more assets based on the emission efficiency, and identifying one or more assets with lower emission efficiency based on the classified one or more assets for predictive maintenance.

In some embodiments, the asset comprises at least one of: an industrial machine, a combustion system, a power generation unit, manufacturing equipment, a heating system, a transportation vehicle, or any other equipment that consumes energy and generates emissions during operation.

In yet another embodiment, an emission management system for generating operational insights from the emission efficiency of an asset is disclosed. The system comprises a data collection module and a processing module. The data collection module is configured to receive input data associated with the asset, where the input data includes at least one of the energy inputs of the asset and asset operating conditions. The processing module is configured to determine an energy output produced by the asset based on the collected input data and determine an emission output of the asset using a predictive emission monitoring system (PEMS) or a predefined statistical formulation. The processing module is further configured to calculate an emission efficiency of the asset based on the collected input data and the emission output of the asset and identify emission limits of the asset based on the calculated emission efficiency, where the emission limits of the asset comprise at least one of target high limits, target low limits, warning high limits, and warning low limits. The processing module is configured to recommend ideal emission limits to be applied to the asset if the identified emission limits require adjustments according to predetermined limits.

In some embodiments, the processing module is further configured to calculate an operational efficiency of the asset based on the collected input data and the determined energy output.

In some embodiments, the processing module is further configured to determine a residual waste energy output generated by the asset.

In some embodiments, the predefined statistical formulation for determining the emission output includes at least one of: an empirical model; a mathematical function based on combustion properties; a lookup table of historical emission data; and/or a regression-based predictive model.

In some embodiments, the processing module is further configured to collect the emission efficiency based on the asset operating conditions over a predetermined period and organize the emission efficiency to determine threshold percentages for defining the ideal emission limits.

In some embodiments, the processing module is further configured to determine emission values associated with the identified emission limits of the asset, aggregate the identified emission limits of the asset over a predetermined time period based on the determined emission values, obtain emission limits of a plurality of assets at a site or a region based on the aggregated emission limits of individual assets, and recommend adjusted emission limits for the asset based on the obtained emission limits to align with a net-neutral emission target year.

In some embodiments, the processing module is further configured to predict year-over-year emission limits of the asset until the net-neutral emission target year.

In some embodiments, the processing module is further configured to adjust the identified emission limits of the asset based on at least one of: energy optimization measures; predictive maintenance strategies; and green energy utilization.

In some embodiments, the processing module is further configured to: compute the emission efficiency as a percentage ratio of the energy inputs to the emission output, classify one or more assets based on the emission efficiency, and identify one or more assets with lower emission efficiency based on the classified one or more assets for predictive maintenance.

In yet another embodiment, a non-transitory computer-readable medium is disclosed, having stored thereon computer-executable instructions that, when executed by a processor, cause the processor to execute a method for generating operational insights from emission efficiency of an asset. The method comprises collecting input data associated with the asset, where the input data includes at least one of energy inputs of the asset and asset operating conditions, and determining an energy output produced by the asset based on the collected input data. The method further comprises determining an emission output of the asset using a predictive emission monitoring system (PEMS) or a predefined statistical formulation, calculating an emission efficiency of the asset based on the collected input data and the emission output of the asset, and identifying emission limits of the asset based on the calculated emission efficiency, where the emission limits of the asset comprise at least one of target high limits, target low limits, warning high limits, and warning low limits. Additionally, the method comprises recommending ideal emission limits to be applied to the asset if the identified emission limits require adjustments according to predetermined limits.

The disclosed method and system provide intelligent, data-driven operational insights from emission efficiency and enable forecasting of emission limits and net-neutral emission target tracking. Further, supporting multiple asset types and operational environments and ensuring assets remain within regulatory and sustainability targets. Lastly, the disclosed method and system facilitate enterprise-wide emission analysis by rolling up data across sites, regions, and operational levels.

This summary is provided to describe select concepts in a simplified form that are further described in the detailed description. This summary is not intended to identify key or essential features of the claimed subject matter, nor is it intended to be used as an aid in determining the scope of the claimed subject matter.

### BRIEF DESCRIPTION OF DRAWINGS

Embodiments of the subject matter will hereinafter be described in conjunction with the following drawing figures, wherein like numerals denote like elements, and:

FIG. 1 illustrates a process flow for the intelligent inference of emission efficiency in assets according to an embodiment of this disclosure;

FIG. 2 illustrates a system architecture for calculating emission efficiency, setting emission limits, and dynamically optimizing asset performance for regulatory compliance and sustainability goals according to an embodiment of this disclosure;

FIG. 3 illustrates a method for generating operational insights from the emission efficiency of an asset according to an embodiment of this disclosure;

FIG. 4 illustrates a system for generating operational insights from the emission efficiency of an asset according to an embodiment of this disclosure; and

FIG. 5 illustrates a schematic diagram of a communication apparatus according to an embodiment of this disclosure.

Further, skilled artisans will appreciate that elements in the drawings are illustrated for simplicity and may not have necessarily been drawn to scale. For example, the flow charts illustrate the method in terms of the most prominent steps involved to help improve understanding of aspects of the present disclosure. Furthermore, in terms of the construction of the apparatus, one or more components of the apparatus may have been represented in the drawings by conventional symbols, and the drawings may show only those specific details that are pertinent to understanding the embodiments of the present disclosure so as not to obscure the drawings with details that will be readily apparent to those of ordinary skill in the art having the benefit of the description herein.

### DETAILED DESCRIPTION

The following description should be read with reference to the drawings, in which like elements in different drawings are numbered in like fashion. The drawings, which are not necessarily to scale, depict examples that are not intended to limit the scope of the disclosure. Although examples are illustrated for the various elements, those skilled in the art will recognize that many of the examples provided have suitable alternatives that may be utilized.

As used in this specification and the appended claims, the singular forms “a”, “an”, and “the” include the plural referents unless the content clearly dictates otherwise. As used in this specification and the appended claims, the term “or” is generally employed in its sense including “and/or” unless the content clearly dictates otherwise.

It is noted that references in the specification to “an embodiment”, “some embodiments”, “other embodiments”, etc., indicate that the embodiment described may include a particular feature, structure, or characteristic, but every embodiment may not necessarily include the particular feature, structure, or characteristic. Moreover, such phrases are not necessarily referring to the same embodiment. Further, when a particular feature, structure, or characteristic is described in connection with an embodiment, it is contemplated that the feature, structure, or characteristic may be applied to other embodiments whether or not explicitly described unless clearly stated to the contrary.

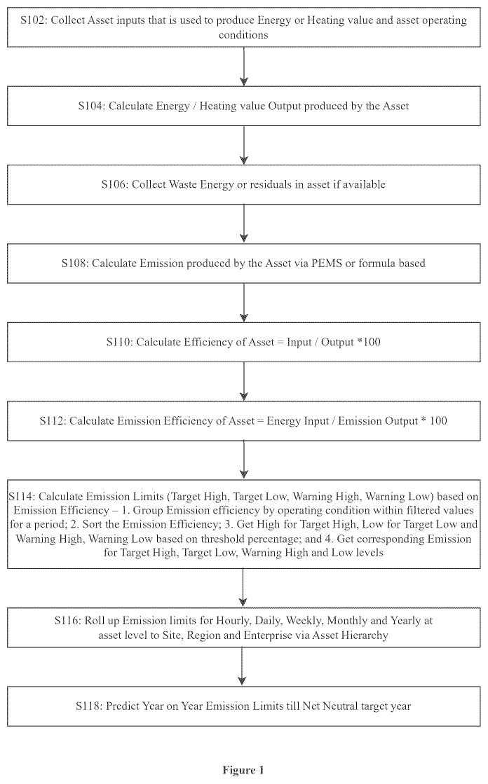

FIG. 1 illustrates a process flow for the intelligent inference of emission efficiency in assets that produce energy or heat while emitting pollutants according to an embodiment of this disclosure. The diagram provides an emission efficiency calculation method and setting of emission limits based on asset-specific operational data.

The first step of the emission efficiency calculation method involves collecting various asset inputs necessary for energy production or heating, as outlined in step S102. These asset inputs encompass a range of parameters critical for evaluating energy efficiency and emissions. According to an embodiment, the key asset inputs include the type of fuel used (such as natural gas, coal, biomass, or hydrogen), the quantity of fuel consumed, and its quality parameters, including calorific value, moisture content, and impurity levels. In addition to fuel-related parameters, the method also accounts for operational parameters that influence the efficiency of energy conversion, such as temperature, pressure, flow rates, and air-to-fuel ratio in combustion processes.

Furthermore, in an embodiment, the asset's operating conditions, such as variations in load demand, start-up and shut-down cycles, and external environmental factors (e.g., ambient temperature, humidity, and altitude), are also considered. The consideration of these operating conditions further helps in determining the overall efficiency and emission characteristics of the asset. For example, a gas turbine operating in a high-altitude region may experience efficiency losses due to lower air density, which in turn affects its emission efficiency. Additionally, the method accommodates variations in energy input due to changes in operational settings, such as partial load operations or peak load conditions, which may impact emission efficiency calculations.

In an embodiment related to greenhouse gas (GHG) and air emissions, the method accounts for real-time variations in fuel composition, combustion parameters, and atmospheric conditions that influence the formation of pollutants such as carbon dioxide (CO₂), nitrogen oxides (NOₓ), and sulfur oxides (SOₓ). For instance, during a cold-start cycle of a power plant, the incomplete combustion of fuel may lead to a temporary spike in CO₂ and methane (CH₄) emissions, affecting overall GHG output. Similarly, increased humidity levels in a coastal region may alter combustion efficiency, potentially leading to higher NOₓ emissions due to incomplete fuel oxidation. By incorporating these factors, the method ensures more accurate emission efficiency calculations and dynamic adjustments to emission thresholds, enabling better compliance with GHG regulations and air quality standards.

In an embodiment, asset-specific constraints and regulatory guidelines are also incorporated at this stage. For example, a power plant may have specific emission thresholds mandated by environmental regulations, which need to be factored into subsequent calculations. By comprehensively collecting all relevant asset inputs, the method ensures an accurate evaluation of energy efficiency and emissions.

In an embodiment, the method includes utilizing advanced sensor-based monitoring systems to enable real-time data acquisition. These sensors measure critical parameters such as fuel flow rate, combustion temperature, oxygen levels in exhaust gases, and energy output, thereby providing precise input data for further processing. Examples of such sensors include mass flow meters for fuel measurement, infrared sensors for temperature detection, and gas analyzers for monitoring emission composition.

Additionally, the method integrates predictive analytics to estimate variations in input parameters based on historical trends. Machine learning models trained on past operational data can forecast fuel consumption rates, expected variations in temperature and pressure, and potential efficiency fluctuations. This predictive capability enables proactive adjustments in operating conditions to optimize energy efficiency and minimize emissions.

For instance, if historical data suggests that a specific fuel type exhibits efficiency degradation over time due to impurities, the system can preemptively recommend adjustments in combustion parameters or suggest alternative fuel blends. In another example, if sensor data indicates an increasing trend in pressure losses due to equipment wear, predictive analytics can trigger maintenance alerts to prevent efficiency drops and excessive emissions.

In some embodiments, the method further incorporates digital twin technology, where a virtual replica of the asset is created to simulate different operating conditions and predict energy efficiency outcomes. The digital twin can run simulations based on real-time sensor inputs, allowing for scenario-based assessments of how different operational strategies affect emissions and efficiency.

In step S104, the method comprises determining the energy or heating value output of an asset based on the processed asset input. This step involves quantifying the net energy generated or the heat produced during the asset's operation. The energy output can be calculated in various ways, depending on the type of asset and the nature of its operation. For assets involved in power generation, such as thermal power plants or gas turbines, the output is measured in terms of electrical energy produced (e.g., in megawatts) or thermal energy transferred (e.g., in joules or BTUs).

For heating systems, including industrial boilers, furnaces, or heat exchangers, the heating value output is determined by measuring the amount of heat transferred to a working fluid (such as steam or heated air) or directly to a process. This calculation often involves parameters such as temperature rise, mass flow rate, and specific heat capacity of the medium being heated.

Additionally, in energy-intensive industries such as metallurgy, chemical processing, and cement manufacturing, energy output is measured in terms of the heat supplied to specific industrial processes. The method accounts for energy losses due to factors such as heat dissipation, radiation losses, and incomplete combustion. The accurate determination of energy output is crucial for evaluating emission efficiency, as it serves as the denominator in emission efficiency calculations, which compare energy input to emission output.

In some embodiments, the method may include real-time monitoring of energy output using advanced metering systems, such as calorimeters, flow meters, and thermocouples, to ensure precise measurement.

In an embodiment, a thermal power plant determines the energy output by calculating the total heat energy generated through the combustion of coal or other fossil fuels. This involves measuring the fuel's calorific value and the efficiency of heat transfer to water or steam within a boiler system. Sensors may be employed to track steam temperature, pressure, and flow rate, enabling accurate estimation of the plant's total energy generation. In some cases, computational models such as Rankine cycle simulations may be used to estimate energy output under different operating conditions.

In an alternate embodiment, a manufacturing unit evaluates the energy output of a boiler system used for industrial heating. The system may involve direct heating of fluids or indirect heat exchange with process materials. The energy output is determined by measuring parameters such as steam pressure, flow rate, and outlet temperature. Additionally, the method may factor in heat losses due to exhaust gases, unburned fuel, and heat transfer inefficiencies.

In another example, a cogeneration or combined heat and power (CHP) plant may calculate both electrical and thermal energy outputs to assess overall system efficiency. The method can also be applied in renewable energy setups, such as biomass plants, where the energy output is determined by evaluating the combustion efficiency of organic materials and the heat energy transferred to a working medium.

Step S106 of the method involves identifying and collecting data on residual energy losses that occur during asset operation. These losses typically arise due to incomplete combustion, unburnt fuel, heat dissipation, and inefficiencies in energy conversion processes. The primary objective of this step is to quantify the energy that is not effectively utilized and determine its impact on the overall efficiency of the asset.

Residual energy losses can occur at multiple points in an energy system. For example, in combustion-based systems such as power plants, boilers, and furnaces, energy losses can result from unburnt fuel losses, heat dissipation losses, excess air losses, fiction and mechanical losses, and electrical losses.

The unburnt fuel losses include incomplete combustion of fuel which can lead to unburnt hydrocarbons or carbon residues in exhaust gases. The heat dissipation losses include heat that may escape from pipes, furnaces, or heat exchangers due to poor insulation or radiative losses. The excess air losses include an inefficient air-fuel ratio that can cause heat loss in flue gases, reducing overall thermal efficiency. The friction and mechanical losses include in turbines, compressors, and rotating machinery, mechanical resistance that may cause energy to be lost as heat rather than useful work. The electrical losses are seen in energy transmission and distribution systems, resistance in conductors and inefficient transformers can lead to power dissipation.

To accurately assess residual energy losses, the method includes real-time monitoring using advanced instrumentation such as thermocouples, infrared sensors, and gas analyzers. Additionally, energy balance equations may be employed to compare input energy, useful output energy, and residual losses. By systematically identifying inefficiencies, operators can take corrective measures such as optimizing combustion parameters, enhancing insulation, or upgrading energy recovery systems to improve overall performance.

In an embodiment, the method employs heat recovery systems to capture and reuse waste heat, thereby reducing energy losses. For example, industrial processes that generate significant heat waste, such as cement manufacturing, chemical processing, and metal refining, can implement waste heat recovery units (WHRUs) or heat exchangers to transfer excess heat to useful applications. The recovered heat can be utilized for preheating incoming fuel, generating additional steam, or powering auxiliary systems.

In an alternate embodiment, the method integrates AI-based pattern recognition to predict and mitigate energy losses in real-time. Machine learning models trained on historical performance data can identify inefficiencies and deviations from optimal operating conditions. For instance, anomaly detection algorithms can monitor temperature, pressure, and fuel consumption to detect abnormal energy losses, predictive analytics can estimate future inefficiencies by analyzing trends in equipment performance, and automated control systems can dynamically adjust operating parameters (e.g., airflow rates, burner configurations) to minimize energy waste.

For example, in a gas turbine system, AI-driven analytics can continuously assess exhaust gas composition and temperature to determine whether unburnt fuel is being wasted. If inefficiencies are detected, the system can recommend or automatically implement corrective actions, such as adjusting fuel injection rates or modifying turbine load distribution.

Step S108 involves determining the emission output of an asset by utilizing monitoring systems such as Predictive Emission Monitoring Systems (PEMS) or formula-based calculations. This step assesses the environmental impact of an asset's operations, ensuring compliance with regulatory standards, and optimizing performance to reduce emissions.

Emission output refers to pollutants released during energy generation or industrial processes, including Carbon dioxide (CO₂), Nitrogen oxides (NOₓ), Sulfur oxides (SOₓ), Particulate matter (PM), and Methane (CH₄) and volatile organic compounds (VOCs).

CO₂ is a major greenhouse gas produced from fossil fuel combustion. NOₓ is formed due to high-temperature combustion, contributing to smog and acid rain. SOₓ is generated from burning sulfur-containing fuels, leading to air pollution. The PM is tiny particles that affect air quality and human health. CH₄ and VOCs are emitted from natural gas processing and chemical plants.

To measure emissions, Continuous Emission Monitoring Systems (CEMS) can be deployed, which use gas analyzers, optical sensors, and mass spectrometers to directly measure pollutant concentrations in flue gases. However, due to the high cost and maintenance of CEMS, many industries use Predictive Emission Monitoring Systems (PEMS), which estimate emissions using machine learning models, process parameters, and historical data.

Formula-based calculations can also be used when direct measurement is impractical. These involve empirical equations derived from experimental data, stoichiometric combustion models that estimate emissions based on fuel composition and operating conditions, and regression-based statistical models for emissions prediction.

In an embodiment, a refinery measures carbon dioxide (CO₂) and nitrogen oxides (NOₓ) emissions from its furnaces, boilers, and flaring systems. This data is used for compliance with environmental regulations such as the U.S. Environmental Protection Agency (EPA) standards, European Union (EU) Industrial Emissions Directive (IED), and India's Central Pollution Control Board (CPCB) guidelines. The refinery may use CEMS for real-time gas measurement or PEMS for cost-effective emissions estimation.

In an alternate embodiment, a gas turbine operator utilizes AI-assisted emissions modeling to enhance regulatory reporting and emissions forecasting. The AI model processes various parameters such as: fuel type and combustion characteristics, ambient temperature and humidity affecting combustion efficiency, load variations impacting emissions profiles.

The AI-driven system can predict emissions under different operating conditions and recommend real-time adjustments, such as modifying air-to-fuel ratios or adjusting turbine speed to minimize NOₓ formation. Additionally, blockchain-based emissions reporting can be integrated to ensure tamper-proof compliance documentation for regulatory authorities.

Step S110 involves calculating the efficiency of an asset, which is a crucial parameter in determining its operational performance and energy utilization effectiveness. Efficiency is expressed as the ratio of input energy to output energy, represented as:

$$Efficiency of asset = ( \frac{Input Energy}{Output Energy} ) \times 100$$

This calculation helps in evaluating whether an asset is operating optimally, inefficiently, or underutilized. A higher efficiency percentage indicates that the asset is converting most of its input energy into useful output, whereas a lower efficiency suggests energy losses due to heat dissipation, incomplete combustion, frictional losses, or suboptimal operating conditions.

The method considers various factors while computing efficiency, including fuel quality and composition, operating conditions, wear and tear, and control system effectiveness. For fuel quality and composition, higher-quality fuels generally result in better combustion efficiency. Operating conditions include factors such as temperature, pressure, and load fluctuations that impact energy conversion efficiency. Wear and tear is mechanical degradation that over time reduces efficiency. Control system effectiveness automates control mechanisms, such as feedback loops and optimization algorithms, to help maintain efficiency.

In practical applications, the efficiency of different assets varies based on the industry and technology used. In a power plant, boiler efficiency is calculated by comparing the heat energy input (from fuel combustion) to the steam energy output. In an internal combustion engine, efficiency is determined by measuring the energy from fuel combustion relative to the mechanical power output. In a manufacturing unit, efficiency is assessed based on the energy consumed versus the product yield. By accurately computing efficiency, organizations can make data-driven decisions to improve asset performance, reduce operational costs, and lower emissions.

Step S112 involves calculating emission efficiency that reflects an asset's effectiveness in converting energy while minimizing emissions. This metric goes beyond absolute emission measurements and provides a comparative efficiency assessment by evaluating how well an asset utilizes its input energy with respect to the emissions it generates. The calculation is expressed as:

$$Efficiency of asset = ( \frac{Energy input}{Emission output} ) \times 100$$

Emission efficiency serves as a more holistic performance indicator compared to traditional emission monitoring methods, which often focus solely on the total quantity of pollutants emitted without considering how efficiently an asset is operating.

Higher emission efficiency means that an asset is generating more energy per unit of emissions, indicating optimal performance and better environmental compliance. Lower emission efficiency suggests higher pollutant output relative to energy input, which may indicate inefficiencies in combustion, fuel composition issues, equipment wear, or inadequate operational controls.

The importance of emission efficiency extends across multiple industries, helping businesses achieve sustainability goals, comply with regulatory emission limits, and optimize operational performance.

In an embodiment, a cement plant compares emission efficiency across multiple kilns. In cement manufacturing, kilns consume significant energy and produce high emissions. Emission efficiency analysis helps identify kilns with suboptimal combustion, excessive energy consumption, or poor fuel quality.

Operators can adjust factors such as kiln temperature, raw material feed rates, and fuel mix to improve efficiency while reducing CO₂ and NOₓ emissions. Over time, emission efficiency trends help plant managers implement best practices across multiple kilns, leading to reduced environmental impact and cost savings.

In an alternate embodiment, a fleet operator uses emission efficiency data to optimize fuel consumption. Transportation and logistics companies manage large fleets of vehicles, where fuel efficiency and emissions are critical concerns. By monitoring emission efficiency for each vehicle, operators can identify trucks or ships with poor fuel combustion leading to excessive emissions, optimize driving patterns, load distribution, and route planning to enhance efficiency, recommend engine maintenance, fuel additive use, or hybrid powertrains for improvement, and AI-driven emission efficiency analytics enable proactive fleet management, helping companies reduce fuel costs, minimize carbon footprint, and comply with emission regulations.

In thermal power plants, emission efficiency is monitored for boilers, turbines, and exhaust systems to optimize energy generation while controlling emissions. AI-based optimization tools adjust combustion air ratios, fuel mix, and turbine loads for higher emission efficiency.

In petroleum refineries, emission efficiency is used to assess furnace and heater performance, ensuring minimal flue gas losses and optimal fuel utilization. Machine learning models analyze historical emission efficiency data to predict degradation patterns and recommend preventive maintenance or operational adjustments.

Digital twins simulate different operational scenarios to determine optimal emission efficiency strategies before real-world implementation.

Step S114 involves calculating emission limits based on emission efficiency, ensuring a structured approach to monitoring, regulating, and optimizing emissions in various industrial and energy-producing environments. These limits are determined by setting threshold levels that categorize operational performance into target and warning levels. The threshold levels considered in this step include target high (best-case efficiency), target low (worst-case efficiency), warning highs, and warning low.

The target high represents an asset operating at optimal emission efficiency, where emissions are at the lowest possible levels relative to input energy. The target low (worst-case efficiency) represents an asset operating at poor efficiency, indicating excessive emissions compared to input energy. The warning high represents an efficiency level that is borderline acceptable but may indicate an impending deterioration in performance or an issue requiring corrective action. The warning low represents an efficiency level that is significantly poor, requiring immediate intervention to prevent excessive emissions, regulatory violations, or operational inefficiencies.

The calculation process involves the following steps grouping emission efficiency by operating conditions, sorting emission efficiency values, identifying high/low values for different thresholds, and associating emissions with these threshold levels.

Grouping emission efficiency by operating conditions includes collecting data from various operational scenarios (e.g., load levels, fuel quality, combustion conditions, ambient temperature). The emission efficiency values are categorized based on these real-world operating conditions. In sorting emission efficiency values, the gathered values are arranged in ascending or descending order to determine trends. This helps identify performance outliers and common efficiency benchmarks.

Identifying high/low values for different thresholds includes determining target high and target low levels based on the best and worst operational efficiencies observed. Warning High and Warning Low levels are identified based on pre-set threshold percentages or historical patterns indicating potential risks.

Associating emissions with these threshold levels, the corresponding emission outputs for each efficiency level are mapped, enabling the system to set emission limits dynamically. By implementing this structured approach, industries can identify and mitigate efficiency-related emission issues in real time, improving compliance with environmental regulations while optimizing fuel usage and operational performance.

In an embodiment, real-time cloud-based analytics are used to set dynamic emission limits. Cloud-based analytics platforms collect and analyze real-time emission efficiency data from multiple assets. AI-driven algorithms adjust emission limits dynamically based on operational conditions, regulatory requirements, and historical performance trends.

For example, in a gas-fired power plant, if emissions approach the warning high threshold, the system automatically adjusts fuel mix or combustion parameters to restore optimal efficiency. This dynamic approach helps reduce regulatory penalties, improve sustainability efforts, and enhance energy efficiency.

In an alternate embodiment, industry-specific benchmarks are used to establish emission targets. Different industries have specific emission standards and efficiency expectations. By comparing operational data with established benchmarks, businesses can ensure compliance with environmental regulations such as those set by EPA, ISO, or other governing bodies.

Set realistic, industry-standard emission targets for continuous improvement initiatives. Implement benchmarking strategies across multiple assets or sites to improve efficiency across the organization. For instance, a cement plant can compare its emission efficiency against global best practices for clinker production, ensuring sustainable and competitive operations.

In industrial manufacturing, factories and heavy machinery plants use emission limit calculations to set maintenance schedules based on efficiency trends. AI-powered diagnostics predict potential emission violations and suggest corrective measures.

In oil refineries and petrochemical plants, emission thresholds help refineries optimize crude processing efficiency while staying within compliance limits. Predictive modeling ensures low emissions even during peak refining operations.

In smart cities and urban infrastructure, emission limits are used in urban energy grids to regulate emissions from distributed energy sources. Cloud-based analytics track emissions from multiple assets such as power plants, industrial sites, and transportation hubs.

In fleet and logistics management, emission efficiency thresholds help fleet operators enforce best practices for vehicle maintenance and fuel optimization. Telematics-based monitoring ensures real-time alerts when emissions cross warning thresholds.

In step S116, roll-up emission limits are determined by aggregating emission data across various timeframes and hierarchical levels within an organization. Thus, enabling comprehensive emission tracking, facilitating regulatory compliance, operational efficiency, and sustainability initiatives. The emission data is categorized based on different timescales, including hourly, daily, weekly, monthly, and yearly roll-ups. Hourly aggregation captures real-time fluctuations, allowing for instantaneous adjustments and automated emission control, while daily and weekly tracking helps in identifying short-term inefficiencies. Monthly and yearly roll-ups provide insights for compliance reporting, maintenance scheduling, and long-term strategic planning.

The roll-up process also involves hierarchical categorization at different organizational levels. At the individual asset level, emission data is recorded from specific machines, boilers, turbines, or production units. This data is then consolidated at the site level, combining emissions from multiple assets within a factory, refinery, or power plant. Regional aggregation integrates emission data from multiple sites within a geographical area, and at the enterprise level, emissions from all regional sites are consolidated to provide a global view. This structured approach ensures that businesses can monitor emissions effectively, identify compliance gaps, and implement targeted interventions to optimize performance.

In an exemplary embodiment, a multinational manufacturing firm consolidates emission data across its global plants using a centralized cloud-based analytics platform. Sensors installed at each plant automatically collect emissions data, which is then analyzed at different levels to track compliance and efficiency trends. If emissions at a particular site exceed benchmarks, automated alerts prompt corrective actions such as adjusting production processes, optimizing fuel consumption, or upgrading emission control systems. This approach enhances corporate environmental responsibility and aligns with international climate regulations.

In another embodiment, a regional regulatory body uses industry-wide emission trends to set compliance benchmarks. By aggregating emissions data from multiple companies, regulatory authorities can establish acceptable thresholds, identify non-compliant entities, and enforce emission reduction policies. AI-driven analytics assist in forecasting emission trends, enabling regulators to implement proactive environmental policies rather than reactive enforcement measures. This method fosters sustainable industrial growth while ensuring adherence to environmental norms and public health standards.

Alternative embodiments include applications in industries such as oil and gas, where refineries and natural gas processing plants monitor greenhouse gas emissions and adjust operations accordingly. In smart cities, governments track emissions from vehicles, power plants, and industrial facilities to draft data-backed air quality regulations. The aviation and shipping industries also utilize roll-up emission data to optimize fuel usage, reduce carbon tax liabilities, and support net-zero initiatives. Large enterprises use hierarchical emission aggregation to track Scope 1, Scope 2, and Scope 3 emissions for Environmental, Social, and Governance (ESG) reporting, ensuring transparency in corporate sustainability efforts.

By systematically consolidating emission data, the roll-up framework enhances regulatory compliance, enables proactive risk management, and supports sustainability goals. It allows organizations to make data-driven decisions, minimize environmental impact, and ensure compliance with evolving emission regulations. This approach not only streamlines emission monitoring but also contributes to global climate action by enabling industries to align their operations with carbon reduction targets and long-term sustainability commitments.

In step S118, Year-on-Year (YoY) emission limit prediction is carried out using predictive analytics to forecast future emission levels and determine progress toward long-term sustainability goals, such as achieving net-zero emissions. This step enables organizations to proactively plan emission reduction strategies, align with regulatory frameworks, and optimize operational efficiency while ensuring environmental compliance. By analyzing historical emission data, operational trends, fuel consumption patterns, and external factors such as regulatory changes and market shifts, predictive models estimate emission limits for upcoming years. These forecasts help in setting realistic reduction targets and evaluating the effectiveness of ongoing emission control measures.

The predictive analytics framework employed in this step integrates multiple data sources, including real-time emissions data, asset performance records, maintenance logs, and environmental conditions. Machine learning algorithms process this information to identify patterns and correlations that influence emission levels. For instance, if a manufacturing plant has shown a gradual decline in emission efficiency due to aging equipment, predictive models can highlight the potential impact on future emissions and suggest proactive maintenance or equipment upgrades to mitigate inefficiencies. By leveraging AI-driven forecasting models, industries can assess emission trends dynamically and take corrective measures before exceeding regulatory thresholds.

In an alternate embodiment, AI-based forecasting incorporates carbon credit market data to provide a comprehensive sustainability tracking mechanism. Carbon credits represent allowances that companies can trade based on their carbon footprint, and integrating this data into emission prediction models enables organizations to make informed decisions regarding carbon offset strategies. For example, a company exceeding its predicted emission limits may opt to invest in renewable energy projects or purchase carbon credits to neutralize its impact. Conversely, organizations operating below their forecasted limits may monetize excess allowances by selling carbon credits in compliance with emission trading schemes.

Another embodiment includes scenario-based modeling, where organizations simulate different operational conditions to assess potential outcomes. For instance, a power plant may analyze multiple scenarios—such as transitioning to a higher percentage of renewable energy sources, implementing advanced emission control technologies, or optimizing fuel combustion efficiency—to determine the most effective pathway toward long-term emission reductions. This allows businesses to develop tailored strategies that balance sustainability with economic feasibility.

Additionally, government agencies and environmental regulators can utilize YoY emission limit prediction to shape climate policies and enforcement measures. By analyzing industry-wide trends, regulatory bodies can establish realistic compliance targets, adjust emission caps, and develop incentives for industries adopting low-emission technologies. For example, a national environmental agency may use AI-based forecasting to predict the collective emissions of power plants over the next decade and implement regulatory frameworks that encourage the adoption of cleaner energy sources.

Beyond industrial applications, the transportation sector can also benefit from YoY emission limit predictions. Fleet operators can assess the long-term impact of transitioning from fossil fuel-based vehicles to electric or hybrid alternatives. By modeling fuel consumption and emission trends, logistics companies can plan investments in green technologies and optimize delivery routes to minimize environmental impact. Similarly, smart cities can leverage predictive analytics to estimate future urban air quality based on transportation policies, energy consumption trends, and industrial emissions, allowing for proactive regulatory adjustments.

By implementing YoY emission limit prediction, businesses, policymakers, and regulatory bodies gain a forward-looking approach to environmental management. This predictive framework enables strategic decision-making, supports sustainability initiatives, and ensures compliance with evolving climate regulations. Ultimately, AI-driven forecasting empowers industries to make data-backed adjustments that align with long-term emission reduction commitments, contributing to a more sustainable and environmentally responsible future.

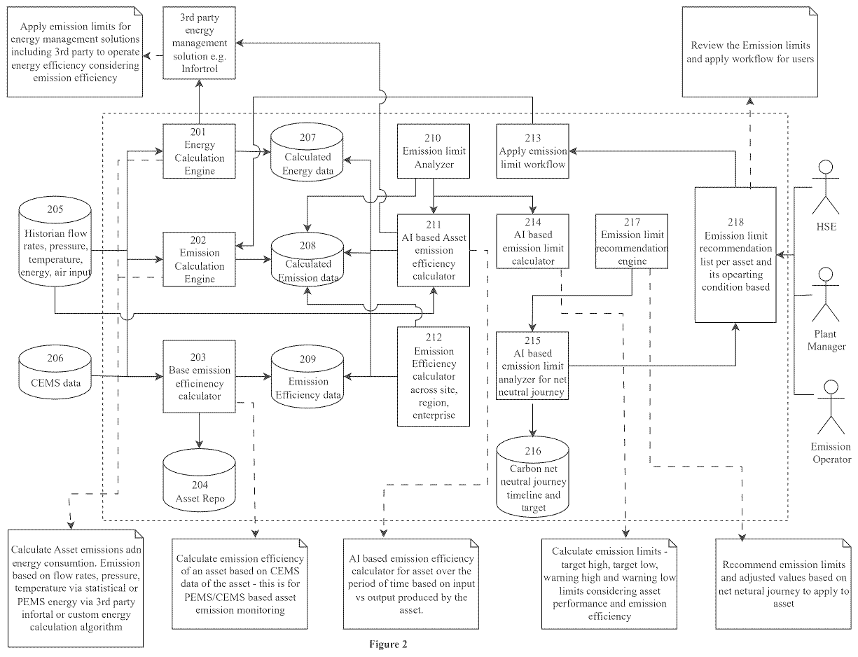

FIG. 2 illustrates a system architecture for calculating emission efficiency, setting emission limits, and dynamically optimizing asset performance for regulatory compliance and sustainability goals according to an embodiment of this disclosure. The framework begins with data acquisition from multiple sources, including historian logs that capture flow rates, pressure, temperature, energy consumption, and air input levels.

Additionally, Continuous Emission Monitoring Systems (CEMS) provide real-time emission data, while third-party energy management solutions contribute external insights on energy usage patterns. This collected data forms the foundation for emission and energy calculations.

At the core of the system, three key computational engines, i.e., energy calculation engine 201, emission calculation engine 202, and base emission efficiency calculator 203, process the acquired data. The energy calculation engine 201 calculates net energy output data based on operational parameters such as fuel consumption and heating value. The net energy output data is stored in the database 207.

Simultaneously, the emission calculation engine 202 computes the volume and type of pollutants released, either through statistical modelling or Predictive Emission Monitoring Systems (PEMS) and is stored in the database 208. The Base Emission Efficiency Calculator 203 then evaluates how effectively the asset converts energy while minimizing emissions by calculating emission efficiency using the ratio of energy input to emission output and stored in the database 209. These computations enable a data-driven approach to emission monitoring and optimization.

Once emission efficiency is determined, the system evaluates emission limits using the module 210 and operational recommendations through AI-driven analytics. The Emission Limit Analyzer 210 establishes threshold values, including Target High, Target Low, Warning High, and Warning Low, ensuring assets operate within optimal efficiency ranges. An AI-based Asset Emission Efficiency Calculator 211 continuously monitors historical and real-time asset performance, detecting trends and variations. At the organizational level, the Emission Efficiency Calculator 212 across Site, Region, and Enterprise consolidates emission data, allowing companies to analyze efficiency trends across multiple facilities. The AI-based Emission Limit Calculator 214 dynamically adjusts permissible emission thresholds based on evolving operational conditions, while the Emission Limit Recommendation Engine 217 generates tailored recommendations for each asset, ensuring emissions remain within prescribed limits.

To operationalize these insights, the system incorporates an automated workflow for applying emission limits. The Apply Emission Limit Workflow 213 ensures that calculated thresholds and recommendations are enforced across all assets. Additionally, the AI-based Emission Limit Analyzer 210 for Net-Neutral Journey evaluates long-term sustainability progress by aligning asset performance with net-zero emissions goals. The Carbon Net Neutral Journey Timeline and Target 216 tracks year-over-year progress toward decarbonization, integrating industry benchmarks and best practices into corporate sustainability initiatives.

The system allows different stakeholders to engage with emission data in a structured manner. HSE teams monitor compliance, while plant managers oversee operational efficiency and ensure that plants adhere to emission targets. Emission operators are responsible for applying recommended adjustments and optimizing energy efficiency. The system also integrates with third-party energy solutions, allowing organizations to compare internal performance with external industry benchmarks. Additionally, Emission-Based Energy Optimization strategies help balance production efficiency with emission reductions, ensuring sustainable industrial operations.

Beyond its core capabilities, the system incorporates real-time emission tracking and reporting to streamline regulatory audits and enhance corporate sustainability tracking. The AI-driven analytics enable organizations to automate emission monitoring, proactively adjust operational parameters, and minimize regulatory risks. This structured and intelligent approach is applicable across multiple industries, including power generation, manufacturing, oil and gas, and transportation, enabling companies to enhance compliance, optimize fuel efficiency, and achieve long-term environmental goals.

A crucial aspect of emission management is the ability to analyze emission efficiency rather than just absolute emission output, enabling industries to make informed decisions about operational performance and maintenance schedules. The disclosure discussed in this document introduces a scenario-based approach to emission efficiency evaluation, demonstrating how a data-driven framework can identify inefficiencies, recommend proactive maintenance, and dynamically adjust emission limits to align with sustainability goals.

Scenario 1: Identifying Low-Performing Assets: In the first scenario, three boilers each produce 100 tons of emissions; however, their emission efficiencies vary significantly—Boiler 1 operates at 93% efficiency, Boiler 2 at 45% efficiency, and Boiler 3 at 70% efficiency. A traditional emissions assessment would consider all three boilers to have an equal environmental impact based on their emission output. However, by factoring in emission efficiency, it becomes clear that Boiler 2 is underperforming relative to the others. A lower efficiency suggests incomplete fuel combustion, excessive energy waste, or operational inefficiencies, making Boiler 2 a prime candidate for predictive maintenance and performance optimization. By addressing these inefficiencies, industries can reduce excess fuel consumption, improve emission efficiency, and enhance overall sustainability.

Scenario 2: High Emitters vs. High Efficiency: In the second scenario, the emission outputs and efficiencies vary across three boilers: Boiler 1 emits 130 tons at 73% efficiency, Boiler 2 emits 50 tons at 45% efficiency, and Boiler 3 emits 200 tons at 80% efficiency. At first glance, Boiler 3 may appear to be the worst performer due to its highest emission output; however, a closer inspection of emission efficiency reveals that it operates more efficiently than Boiler 2, meaning it optimally converts fuel into energy while minimizing waste residuals. Conversely, Boiler 2, despite having the lowest absolute emissions, operates at only 45% efficiency, indicating suboptimal performance and potential for operational improvements. This scenario highlights the necessity of emission efficiency-based assessments rather than absolute emission measurements to make informed maintenance and sustainability decisions.

Scenario 3: Dynamic Daily Limit Calculation and Threshold Warnings: To further enhance emission management, the disclosure incorporates daily limit calculations with predefined warning thresholds. The system evaluates daily emission output and efficiency trends for multiple boilers, identifying performance fluctuations over time. Table 1 presents the daily emissions and efficiency levels recorded for each boiler over three days:

TABLE 1

| Boiler | Emission (tons) | Efficiency (%) | Day |
|---|---|---|---|
| Boiler 1 | 70 | 83 | Day 2 |
| Boiler 1 | 75 | 65 | Day 3 |
| Boiler 1 | 100 | 53 | Day 1 |
| Boiler 2 | 70 | 70 | Day 2 |
| Boiler 2 | 50 | 45 | Day 1 |
| Boiler 2 | 80 | 65 | Day 3 |
| Boiler 3 | 100 | 80 | Day 2 |
| Boiler 3 | 150 | 70 | Day 3 |
| Boiler 3 | 200 | 50 | Day 1 |

From this data, it is evident that boiler efficiency fluctuates significantly over time, requiring continuous monitoring and adaptive emission limit adjustments. For example, Boiler 3 exhibited an efficiency drop from 80% on Day 2 to 50% on Day 1, while Boiler 1 dropped from 83% efficiency on Day 2 to 53% on Day 1, signaling potential inefficiencies in combustion, operational settings, or fuel quality.

To establish target and warning limits, the system defines target high and low values along with warning thresholds set at 15%, calculated as follows in Table 2:

TABLE 2

| | Target | Target | Warning High | Warning Low |
|---|---|---|---|---|
| Boiler | High | Low | (+15%) | (−15%) |
| Boiler 1 | 70 | 0 | 80.5 | 59.5 |
| Boiler 2 | 70 | 50 | 80.5 | 59.5 |
| Boiler 3 | 100 | 0 | 115 | 85 |

By implementing these dynamic emission thresholds, industries can receive early warnings before efficiency drops significantly, allowing for proactive adjustments such as fuel optimization, operational fine-tuning, or maintenance scheduling. This approach ensures that assets consistently operate within optimal efficiency ranges, reducing unexpected downtimes and unnecessary regulatory penalties.

Net-Neutral Journey and Predictive Roll-Up: Beyond real-time efficiency monitoring, the system also incorporates predictive analytics to estimate year-end emissions and align with net-neutral sustainability goals. Using historical emission trends, operational patterns, and AI-driven forecasting models, the algorithm predicts future emissions at asset, site, regional, and enterprise levels. Based on this prediction, the system adjusts and recommends emission limits that progressively align with long-term carbon neutrality targets. For example, if a facility is projected to exceed its annual carbon target, the algorithm can suggest optimized operational settings, carbon offset strategies, or process adjustments to ensure compliance.

By integrating real-time efficiency monitoring with predictive emission control, the disclosure bridges the gap between current asset performance and long-term sustainability commitments. This dynamic, data-driven framework helps organizations achieve net-zero targets more effectively, optimize operational efficiency, and reduce overall environmental impact, marking a significant improvement over conventional static emission management strategy.

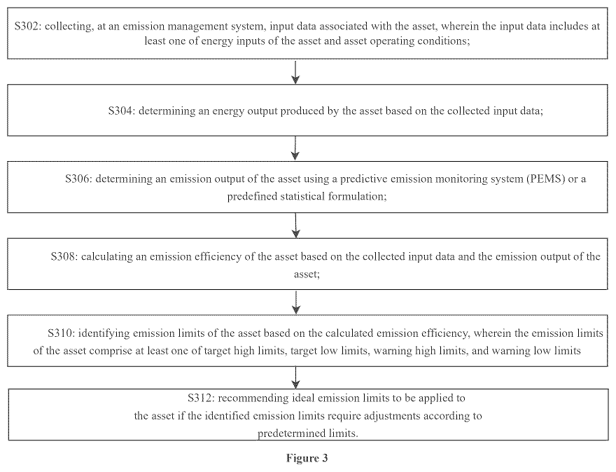

FIG. 3 illustrates a method for generating operational insights from emission efficiency of an asset, enabling organizations to optimize asset performance while ensuring compliance with environmental regulations according to an embodiment of this disclosure. The method begins at step S302 with data collection at an emission management system, where input data is retrieved from various asset sources. The collected input data includes energy inputs (such as fuel type, quantity, and efficiency) and operating conditions (such as temperature, pressure, and load variations). In some embodiments, the asset may be an industrial machine, combustion system, power generation unit, manufacturing equipment, heating system, or transportation vehicle, or any other energy-consuming equipment that generates emissions.

Once the data is collected, the method at step S304 determines the energy output of the asset based on fuel conversion efficiency, thermodynamic properties, and historical performance benchmarks. Simultaneously, at step S306 the emission output is calculated using either Predictive Emission Monitoring Systems (PEMS) or predefined statistical formulations. In some embodiments, the predefined formulation includes empirical models, mathematical combustion equations, historical lookup tables, or regression-based predictive models. For example, in a coal-fired power plant, emission predictions may rely on combustion chemistry equations, whereas in an automotive fleet, AI-driven historical emissions analysis may be utilized.

The method then at step S308 computes the emission efficiency of the asset, defined as the percentage ratio of energy input to emission output. This efficiency metric helps classify assets based on their performance and environmental impact, allowing identification of low-emission efficiency assets for predictive maintenance. For example, a gas turbine operating at 45% emission efficiency compared to another turbine at 85% efficiency may indicate fuel combustion inefficiencies, air-fuel ratio imbalances, or equipment degradation, necessitating proactive maintenance.

Following emission efficiency calculation, the method identifies and establishes emission limits for the asset at step S310, which include target high limits, target low limits, warning high limits, and warning low limits. These limits provide thresholds that differentiate normal operating conditions from inefficient or excessive emission scenarios. In some embodiments, the method organizes historical emission efficiency trends over a predetermined period and determines threshold percentages for defining ideal emission limits. This ensures that organizations can set dynamic emission thresholds based on real-world operating conditions rather than static regulatory limits.

To ensure compliance and optimization, the method recommends adjustments to emission limits if the identified thresholds exceed predefined regulatory or operational limits at step S312. For instance, in a large-scale steel manufacturing plant, real-time emission tracking could trigger automatic emission limit recalibration to maintain compliance with environmental regulations. Similarly, in a fleet management scenario, vehicles exceeding predefined NOₓ or CO₂ limits could be scheduled for engine tuning, route optimization, or alternative fuel usage.

Additionally, in some embodiments, the method computes the operational efficiency of the asset based on energy input, energy output, and emission performance. This holistic approach enables organizations to balance productivity with sustainability, ensuring that assets operate at maximum efficiency while minimizing environmental impact. The method may also determine residual waste energy output, such as heat dissipation in a boiler or unburnt fuel in an engine, which can be repurposed using waste heat recovery systems or other energy optimization strategies.

Beyond individual asset analysis, the method aggregates emission data across multiple time periods and operational levels, including site, regional, and enterprise-wide roll-ups. It determines emission values associated with identified limits and consolidates them over hourly, daily, monthly, and yearly intervals. This allows for enterprise-wide tracking of emissions, providing insights into overall sustainability trends and areas requiring intervention. For example, an oil refinery operating in multiple locations may track emission efficiency across sites, helping identify underperforming plants requiring operational improvements.

In alignment with net-zero emission goals, the method integrates predictive analytics to forecast year-over-year emission limits. The system projects future emissions based on historical trends, operational improvements, and policy-driven targets, ensuring that assets progressively move toward net-neutral emissions. Organizations can use this predictive model to simulate different sustainability strategies, such as switching to renewable energy sources, implementing carbon capture technologies, or optimizing combustion efficiency.

To further support emission reduction efforts, the method adjusts identified emission limits based on energy optimization measures, predictive maintenance strategies, and green energy utilization. For example, an industrial furnace exceeding target emission levels may trigger automated fuel adjustments, while a logistics company may receive recommendations to increase electric vehicle adoption to improve fleet-wide emission efficiency.

By integrating real-time data collection, AI-driven emission analysis, predictive modeling, and dynamic threshold adjustments, this method enables industries to transition toward sustainable operations, enhance regulatory compliance, and optimize asset performance. The disclosure supports a wide range of industries, including power generation, transportation, manufacturing, and oil & gas, by offering data-driven insights for long-term environmental sustainability.

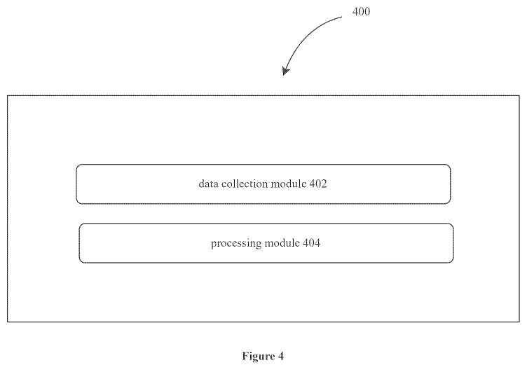

FIG. 4 illustrates an emission management system 400 designed to generate operational insights from an asset's emission efficiency according to an embodiment of this disclosure. This system 400 plays a critical role in monitoring, analyzing, and optimizing emissions while ensuring assets operate efficiently within regulatory compliance limits. The system 400 comprises two primary components: a data collection module 402 and a processing module 404.

The data collection module 402 is responsible for gathering input data related to the asset's operations. This input data includes energy inputs such as fuel type, quantity, and energy consumption rates, as well as operating conditions like temperature, pressure, load variations, and environmental factors. In various embodiments, this module interfaces with multiple sources, including industrial sensors, IoT-based monitoring systems, and third-party energy management platforms, ensuring real-time and historical data acquisition for accurate emission analysis.

The processing module 404 is a computational engine designed to analyze the collected data and generate meaningful insights. The processing module 404 determines the energy output of the asset based on fuel-to-energy conversion efficiencies, thermodynamic calculations, and historical performance trends. Simultaneously, the processing module 404 calculates the emission output using a Predictive Emission Monitoring System (PEMS) or predefined statistical models. These models may include empirical equations, combustion-based mathematical functions, historical lookup tables, and AI-driven regression-based predictive models. By employing these adaptive modeling techniques, the system ensures accurate emission estimations even in cases where direct Continuous Emission Monitoring Systems (CEMS) are unavailable.

A key function of the processing module 404 is computing the emission efficiency of the asset. Emission efficiency is determined as the ratio of energy input to emission output, providing a critical performance metric that highlights how effectively an asset converts fuel into useful energy while minimizing waste emissions. The system classifies assets based on their emission efficiency and identifies underperforming assets for predictive maintenance and performance optimization. For example, a boiler operating at 45% emission efficiency compared to a similar boiler operating at 85% efficiency would be flagged for operational adjustments, combustion tuning, or component upgrades to improve its performance.

Once emission efficiency is determined, the processing module 404 identifies emission limits for the asset, which include target high limits, target low limits, warning high limits, and warning low limits. These limits help organizations set dynamic thresholds for emission compliance while allowing flexibility based on real-world operating conditions. The system continuously monitors and organizes emission efficiency data over a predefined period, allowing for adaptive threshold recalculations. This ensures that businesses maintain optimal performance while proactively mitigating the risk of exceeding regulatory limits.

In cases, where emission limits require adjustments, the system 400 recommends optimized thresholds based on predefined regulatory or operational standards. For example, in a cement manufacturing plant, if real-time data indicates that emissions have consistently been exceeding warning high limits, the system 400 may suggest modifying fuel compositions, optimizing combustion parameters, or introducing secondary emission control mechanisms such as carbon capture.

The processing module 404 also provides higher-level emission insights by aggregating emission limits across multiple assets and locations. The processing module 404 determines emission values associated with identified thresholds, consolidating them over various timeframes such as hourly, daily, monthly, and yearly roll-ups. This feature enables enterprise-wide emission tracking, supporting organizations in achieving sustainability targets while maintaining productivity. For instance, in a large-scale power generation company operating multiple plants across different regions, the system 400 would aggregate emissions data from all sites, identify regional discrepancies, and propose standardized adjustments to ensure uniform compliance.

In alignment with net-zero emissions strategies, the system 400 incorporates predictive analytics to forecast year-over-year emission limits. By analyzing historical data trends, machine learning models project future emission levels, allowing organizations to adjust operational strategies in advance. For example, a transportation fleet operator using diesel-powered trucks may use this system to predict future emissions and plan gradual electrification of their fleet to meet decarbonization goals.

To further support emission reduction efforts, the system 400 dynamically adjusts emission limits based on: Energy Optimization Measures-Enhancing fuel efficiency through alternative fuel integration, combustion optimization, and waste heat recovery; Predictive Maintenance Strategies-Using AI-driven diagnostics to anticipate equipment failures and schedule proactive servicing to maintain emission efficiency; Green Energy Utilization-Suggesting renewable energy adoption, such as solar, wind, or biofuels, in hybrid energy systems to minimize environmental impact.

Additionally, the processing module 404 automates asset classification based on emission efficiency. The processing module 404 identifies assets that fall below efficiency benchmarks and recommends appropriate corrective actions. In industries such as oil refining, chemical processing, and automotive manufacturing, this capability ensures that emission-heavy operations can progressively reduce their carbon footprint while maintaining output efficiency.

By integrating real-time monitoring, AI-driven predictive analytics, and automated emission limit optimization, the emission management system 400 provides organizations with actionable intelligence to improve asset performance, ensure regulatory compliance, and drive long-term sustainability initiatives. This system 400 finds applications in power plants, industrial manufacturing, oil and gas, logistics, and smart city infrastructures, enabling businesses and governments to transition toward data-driven, environmentally responsible operations.

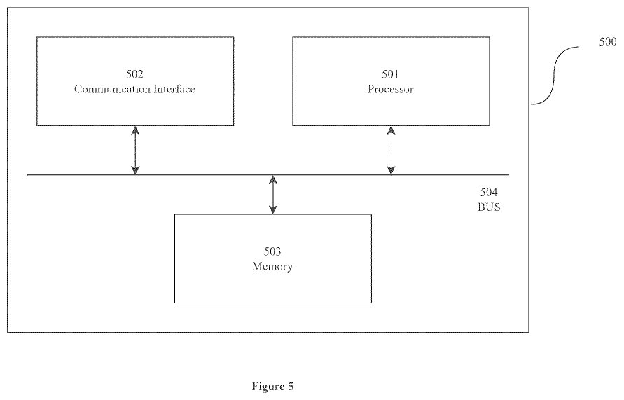

FIG. 5 illustrates a schematic diagram of another communication apparatus 500 according to an embodiment of the disclosure. The communication apparatus 500 includes a processor 501, a communication interface 502, and a memory 503. The processor 501, the communication interface 502, and the memory 503 may be connected to each other via a bus 504. The bus 504 may be a peripheral component interconnect (peripheral component interconnect, PCI) bus, an extended industry standard architecture (extended industry standard architecture, EISA) bus, or the like. The bus 504 may be classified into an address bus, a data bus, a control bus, and the like. For ease of representation, the bus is represented by using only one line in FIG. 4, but it does not indicate that there is only one bus or one type of bus. The processor 501 may be a central processing unit (central processing unit, CPU), a network processor (network processor, NP), or a combination of a CPU and an NP. The processor may further include a hardware chip. The hardware chip may be an application-specific integrated circuit (application-specific integrated circuit, ASIC), a programmable logic device (programmable logic device, PLD), or a combination thereof. The PLD may be a complex programmable logic device (complex programmable logic device, CPLD), a field-programmable gate array (field-programmable gate array, FPGA), generic array logic (Generic Array Logic, GAL), or any combination thereof. The memory 503 may be a volatile memory or a non-volatile memory or may include a volatile memory and a non-volatile memory. The non-volatile memory may be a read-only memory (read-only memory, ROM), a programmable read-only memory (programmable ROM, PROM), an erasable programmable read-only memory (erasable PROM, EPROM), an electrically erasable programmable read-only memory (electrically EPROM, EEPROM), or a flash memory. The volatile memory may be a random-access memory (random access memory, RAM), and is used as an external cache.

The connecting lines shown in the various figures contained herein are intended to represent exemplary functional relationships and/or physical couplings between the various elements. It should be noted that many alternative or additional functional relationships or physical connections may be present in an embodiment of the subject matter.

The subject matter may be described herein in terms of functional and/or logical block components, and with reference to symbolic representations of operations, processing tasks, and functions that may be performed by various computing components or products. It should be appreciated that the various block components shown in the figures may be realized by any number of hardware components configured to perform the specified functions. For example, an embodiment of a system or a component may employ various integrated circuit components, e.g., memory elements, digital signal processing elements, logic elements, look-up tables, or the like, which may carry out a variety of functions under the control of one or more microprocessors or other control products. Furthermore, embodiments of the subject matter described herein can be stored on, encoded on, or otherwise embodied by any suitable non-transitory computer-readable medium as computer-executable instructions or data stored thereon that, when executed (e.g., by a processing system), facilitate the processes described above.

The foregoing description refers to elements or nodes or features being “coupled” together. As used herein, unless expressly stated otherwise, “coupled” means that one element/node/feature is directly or indirectly joined to (or directly or indirectly communicates with) another element/node/feature, and not necessarily mechanically. Thus, although the drawings may depict one exemplary arrangement of elements directly connected to one another, additional intervening elements, products, features, or components may be present in an embodiment of the depicted subject matter. In addition, certain terminology may also be used herein for the purpose of reference only, and thus are not intended to be limiting.

The foregoing detailed description is merely exemplary in nature and is not intended to limit the subject matter of the application and uses thereof. Furthermore, there is no intention to be bound by any theory presented in the preceding background, brief summary, or the detailed description.

While at least one exemplary embodiment has been presented in the foregoing detailed description, it should be appreciated that a vast number of variations exist. It should also be appreciated that the exemplary embodiment or exemplary embodiments are only examples, and are not intended to limit the scope, applicability, or configuration of the subject matter in any way. Rather, the foregoing detailed description will provide those skilled in the art with a convenient road map for implementing an exemplary embodiment of the subject matter. It should be understood that various changes may be made in the function and arrangement of elements described in an exemplary embodiment without departing from the scope of the subject matter as set forth in the appended claims. Accordingly, details of the exemplary embodiments or other limitations described above should not be read into the claims absent a clear intention to the contrary.

What is claimed is:

1. A method for generating operational insights from emission efficiency of an asset, the method comprising:
collecting, at an emission management system, input data associated with the asset, wherein the input data includes at least one of energy inputs of the asset and asset operating conditions;
determining an energy output produced by the asset based on the collected input data;
determining an emission output of the asset using a predictive emission monitoring system (PEMS) or a predefined statistical formulation;
calculating an emission efficiency of the asset based on the collected input data and the emission output of the asset;
identifying emission limits of the asset based on the calculated emission efficiency, wherein the emission limits of the asset comprise at least one of target high limits, target low limits, warning high limits, and warning low limits; and
recommending ideal emission limits to be applied to the asset if the identified emission limits require adjustments according to predetermined limits.

2. The method of claim 1, further comprising calculating an operational efficiency of the asset based on the collected input data and the determined energy output.

3. The method of claim 1, further comprising determining a residual waste energy output generated by the asset.

4. The method of claim 1, wherein the predefined statistical formulation for determining the emission output includes at least one of:
an empirical model;
a mathematical function based on combustion properties;
a lookup table of historical emission data; and/or
a regression-based predictive model.

5. The method of claim 1, further comprising collecting the emission efficiency based on the asset operating conditions over a predetermined period and organizing the emission efficiency to determine threshold percentages for defining the ideal emission limits.

6. The method of claim 1, further comprising:
determining emission values associated with the identified emission limits of the asset;
aggregating the identified emission limits of the asset over a predetermined time period based on the determined emission values;
obtaining emission limits of a plurality of assets at a site or a region based on the aggregated emission limits of individual assets; and
recommending adjusted emission limits for the asset based on the obtained emission limits to align with a net-neutral emission target year.

7. The method of claim 6, further comprising predicting year-over-year emission limits of the asset until the net-neutral emission target year.

8. The method of claim 1, further comprising adjusting the identified emission limits of the asset based on at least one of:
energy optimization measures;
predictive maintenance strategies; and
green energy utilization.

9. The method of claim 1, wherein calculating the emission efficiency of the asset comprises:
computing the emission efficiency as a percentage ratio of the energy inputs to the emission output;
classifying one or more assets based on the emission efficiency; and
identifying one or more assets with lower emission efficiency based on the classified one or more assets for predictive maintenance.

10. The method of claim 1, wherein the asset comprises at least one of:
an industrial machine;
a combustion system;
a power generation unit;
a manufacturing equipment;
a heating system;
a transportation vehicle; or
any other equipment that consumes energy and generates emissions during operation.

11. An emission management system for generating operational insights from emission efficiency of an asset, the system comprising:
a data collection module configured to receive input data associated with the asset, wherein the input data includes at least one of energy inputs of the asset and asset operating conditions; and
a processing module configured to:
determine an energy output produced by the asset based on the collected input data;
determine an emission output of the asset using a predictive emission monitoring system (PEMS) or a predefined statistical formulation;
calculate an emission efficiency of the asset based on the collected input data and the emission output of the asset;
identify emission limits of the asset based on the calculated emission efficiency, wherein the emission limits of the asset comprise at least one of target high limits, target low limits, warning high limits, and warning low limits; and
recommend ideal emission limits to be applied to the asset if the identified emission limits require adjustments according to predetermined limits.

12. The emission management system of claim 11, wherein the processing module is further configured to calculate an operational efficiency of the asset based on the collected input data and the determined energy output.

13. The emission management system of claim 11, wherein the processing module is further configured to determine a residual waste energy output generated by the asset.

14. The emission management system of claim 11, wherein the predefined statistical formulation for determining the emission output includes at least one of:
an empirical model;
a mathematical function based on combustion properties;
a lookup table of historical emission data; and/or
a regression-based predictive model.

15. The emission management system of claim 11, wherein the processing module is further configured to collect the emission efficiency based on the asset operating conditions over a predetermined period and organize the emission efficiency to determine threshold percentages for defining the ideal emission limits.

16. The emission management system of claim 11, wherein the processing module is further configured to
determine emission values associated with the identified emission limits of the asset;
aggregate the identified emission limits of the asset over a predetermined time period based on the determined emission values;
obtain emission limits of a plurality of assets at a site or a region based on the aggregated emission limits of individual assets; and
recommend adjusted emission limits for the asset based on the obtained emission limits to align with a net-neutral emission target year.

17. The emission management system of claim 16, wherein the processing module is further configured to predict year-over-year emission limits of the asset until the net-neutral emission target year.

18. The emission management system of claim 11, wherein the processing module is further configured to adjust the identified emission limits of the asset based on at least one of:
energy optimization measures;
predictive maintenance strategies; and
green energy utilization.

19. The emission management system of claim 11, wherein the processing module is further configured to:
compute the emission efficiency as a percentage ratio of the energy inputs to the emission output;
classify one or more assets based on the emission efficiency; and
identify one or more assets with lower emission efficiency based on the classified one or more assets for predictive maintenance.

20. A non-transitory computer-readable medium having stored thereon computer-executable instructions that, when executed by a processor, cause the processor to execute a method for generating operational insights from emission efficiency of an asset, comprising:
collecting input data associated with the asset, wherein the input data includes at least one of energy inputs of the asset and asset operating conditions;
determining an energy output produced by the asset based on the collected input data;
determining an emission output of the asset using a predictive emission monitoring system (PEMS) or a predefined statistical formulation;
calculating an emission efficiency of the asset based on the collected input data and the emission output of the asset;
identifying emission limits of the asset based on the calculated emission efficiency, wherein the emission limits of the asset comprise at least one of target high limits, target low limits, warning high limits, and warning low limits; and
recommending ideal emission limits to be applied to the asset if the identified emission limits require adjustments according to predetermined limits.
